(19) United States
(12) Patent Application Publication
(10) Pub. No.: US 2007/0252126 A1
(43) Pub. Date: Nov. 1, 2007

(54) Driver and Drive Method for Organic Bistable Electrical Device and Organic Led Display

(76) Inventors: Haruo Kawakami, Tokyo (JP); Yang Yang, Los Angeles, CA (US); Liping Ma, Los Angeles, CA (US)

Correspondence Address: RABIN & Berdo, PC, 1101 14TH STREET, NW, SUITE 500, WASHINGTON, DC, 20005, US

(21) Appl. No.: 10/592,079

(22) PCT Filed: Mar. 15, 2005
(86) PCT No.: PCT/US05/08478

§ 371 Date: Jun. 7, 2007

Related U.S. Application Data
(60) Provisional application No. 60/553,574, filed on Mar. 15, 2004.

(51) Int. Cl. H01L 47/00; H01L 51/00

(52) U.S. Cl. 257/2; 438/99; 257/E51.001; 257/E47.001

(57) ABSTRACT

An electroluminescent device based on bistability, and method for its use. The device alternates between a low resistance state and a high resistance state by application of an electrical voltage. A bistable electrical device has two electrodes sandwiching an organic material that produces bistable action. An organic light emitting diode next to the bistable device is emits light when conducting. To achieve graduated light output, circuitry is provided for applying to the bistable device a constant bias voltage intermediate a turnoff voltage and a turn-on voltage, and electrical pulses variable in a temporal pulse width or in an additional voltage, or in both. The additional voltage is superimposed on the bias voltage while the pulse is applied. The current through the bistable device, and therefore the brightness of light emitted by the diode after the pulse has ceased, are controlled by varying the pulse width or the additional voltage.

### CROSS-REFERENCE TO RELATED APPLICATION

This application claims benefit of the applicants' Provisional Application 60/553,574, filed on Mar. 15, 2004, the entire disclosure of which is incorporated herein be reference.

### BACKGROUND OF THE INVENTION

1. Field of the Invention

The invention relates to a driving method for a switching device in which an organic bistable material is disposed between two electrodes, and more particularly to a switching device for driving an organic electroluminescent display panel, or a high-density memory or the like.

2. Description of Related Art

In recent years, there has been remarkable progress in the properties of organic electronic materials. In particular, with regard to so-called organic bistable materials that exhibit a switching phenomenon in which if a voltage is applied to the material then the circuit current suddenly increases at no less than a certain voltage. Studies have been carried out into application to switching devices for driving organic EL (electroluminescent) display panels, high-density memories and so on.

Yang et al., in an article entitled “Organic bistable light-emitting devices” in Applied Physics Letters, Jan. 21, 2002 (Appl. Phys. Lett. 80, (2002) 362) describe a bistable electrical device having two outer electrodes and a core of organic electronic material that contains a thin film of metal. This device has two states, conducting and non-conducting, which are both stable for a long time and within a wide range of applied voltages that do not exceed a write (positive) or erase (negative) voltage. The two states differ in their conductivities by a factor of 10⁷.

The above-mentioned Yang et al. article is entirely incorporated herein by reference.

FIG. 2 of the article shows the behavior of the bistable electrical device. It remains non-conducting up to an applied voltage of about 3 volts, at which point it suddenly increases its conductivity, with the current increasing from 10⁻⁸ amperes to more than 10⁻³ amperes. When the applied voltage is then decreased, the current remains above 10⁻³ amperes until the voltage drops below a volt, and stays above 10⁻⁴ amperes until the voltage is close to zero. Moreover, the conducting state remains even after the voltage is removed entirely, so that a memory built from such a device is non-volatile.

Yang et al. also describe a bistable electrical device combined with a polymer LED (PLED) to make a memory device that has both an electrical and an optical readout. FIG. 4 of the Yang article shows the behavior of this OBLED (organic bistable light emitting device). The bistability occurs between 2 volts and 6 volts in the OBLED. No light is emitted until the voltage increases up to 6 volts, but light emission continues as the voltage is decreased below 6 volts. Because of this, the device will emit light when 4 volts is applied, if it has been subjected to 6 volts or more; but it will not emit as much light when 4 volts is applied, if it has not been subjected to 6 volts or more. The difference in light output is of the order of 100 times. Yang et al. state that this difference in light output can be used in a memory and that the memory cells can be read out in parallel, unlike conventional memories that are read serially (page 364, lines 14-28).

Yang et al. do not disclose using the OBLED as a display except where the OBLED's are in either a fully-light-emitting state (at 4 volts after being driven to a conducting state by voltage above 6 volts) or an fully-non-light-emitting state (at 4 volts before being driven to a conducting state by voltage above 6 volts).

International Published Application WO 02/37500 to Yang et al. (the entire subject matter and contents of which are incorporated herein by reference) also describes the use of bistable electrical devices for memory cells. This publication notes that threshold switching and memory phenomena have been demonstrated in both organic and inorganic thin-film semiconductor materials such as amorphous chalcogenide semiconductor, amorphous silicon, organic material and ZnSe—Ge heterostructures, and describes their use in memory devices.

This publication also notes that a number of organic functional materials have attracted attention for potential use in light emitting diodes and triodes (citing J. H. Burroughes, D. D. C. Bradley, A. R. Brown, R. N. Marks, K. Mackay, R. H. Friend, P. L. Burn, and A. B. Holmes, Nature, 347, 539 (1990), and Y. Yang et al., U.S. Pat. No. 5,563,424, Oct. 8, 1996, incorporated herein by reference). The publication further notes that electroluminescent polymers are one of the organic functional materials that have been investigated for use in display applications.

Various organic complexes are known for use as organic bistable materials that exhibit such a nonlinear response. For example, R. S. Potember et al. have carried out trial manufacture of a switching device having two stable resistance values to a voltage using a Cu-TCNQ (copper-tetracyanoquinodimethane) complex (R. S. Potember et al., Appl. Phys. Lett. 34, (1979) 405).

Kumai et al. have observed switching behavior due to nonlinear response using a single crystal of a K-TCNQ (potassium-tetracyanoquinodimethane) complex (Kumai et al., Kotai Butsuri (Solid State Physics), 35 (2000) 35).

Adachi et al. have formed a Cu-TCNQ complex thin film using a vacuum deposition method, elucidated the switching behavior thereof, and carried out studies into the possibility of application to an organic EL matrix (Adachi et al., Proceedings of the Japan Society of Applied Physics, Spring 2002, Vol. 3, 1236).

Incorporated herein in their entirely by reference, along with references cited therein, are the following: Yang et al., Organic bistable electrical devices and their applications, Polymer Preprints 2002, 43(2), 512; Yang et al., Nonvolatile bistability of organic/metal-nanocluster/organic system, Appl. Phys. Lett. vol. 82 no. 9, p. 1419 (Mar. 3, 2003); Yang et al., Organic electrical bistable electrical devices and rewritable memory cells, Appl. Phys. Lett. vol. 80 no. 16, p. 2997 (Apr. 22, 2002).

### SUMMARY OF THE INVENTION

As mentioned above, Yang et al. have shown that bistable behavior can be obtained.

This behavior can be obtained by forming a thin film of, or dispersing fine particles of, a material having a high electrical conductance such as gold, silver, aluminum, copper, nickel, magnesium, indium, calcium or lithium in a material having a low electrical conductance such as aminoimidazole dicarbonitrile (AIDCN), aluminum quinoline, polystyrene or polymethyl methacrylate (PMMA).

The invention relates to a driving method for such devices, or other bistable devices, and to a switching device in which an organic bistable material is disposed between two electrodes and is used as a switching device for driving an organic EL display panel, preferably in a high-density memory or the like.

FIG. 6 shows an example of the voltage-current characteristic of such an organic bistable material exhibiting switching behavior. There are two states, a high resistance state 51 (OFF state) and a low resistance state 52 (ON state). The nonlinear response characteristic is embodied in FIG. 6 as follows: starting from a state in which a bias voltage Vb has been applied in advance, if the applied voltage is increased to a first threshold voltage Vth2 or above, then a transition from the OFF state to the ON state takes place. After this transition, if the voltage is decreased to a second threshold voltage Vth1 or below, the device will again transition, but this time a transition from the ON state to the OFF state takes place, with the resistance value changing.

That is, a “switching” operation can be carried out by applying to the organic bistable material a voltage not less than Vth2 (switching on) or not more than Vth1 (switching off). The voltage of no more than Vth1 or no less than Vth2 can be applied as a voltage pulse.

The invention contemplates that the switching device is connected in series with an organic light emitting diode. By holding the voltage at the bias voltage Vb, the organic light emitting diode can be held in an ON or OFF state, and by applying a voltage no less than Vth2 or no more than Vth1, a switching operation can be carried out.

However, if such a constitution is adopted for each of the pixels of a passive matrix display, then whether the emission of light is on or off for each pixel is set within the duty time, and then subsequently that state is held during the frame period. As a result, the need for emission of light with high brightness within the duty time, which was a shortcoming of conventional passive matrixes, is eliminated, and the light emission efficiency and the lifetime of the panel can be improved.

The above-described switching has the following drawbacks. There are only two states, ON and OFF, and hence only two light emission states are possible; it is thus not possible to achieve, with a single pixel, gradation of light levels, which is required for many displays. Moreover, the electrical resistance of the light emitter increases with the operating time, and hence the current is not constant with an applied voltage. In order to make the light emission lifetime long, it would be desirable to have the driving current, not the voltage, constant, but with the driving method described above this cannot be achieved.

One object of the invention is to drive the pixels with constant current, and another is to achieve a gradation of the instantaneous luminosity of each pixel.

Preferably in the invention a switching device includes an organic bistable material disposed between two electrodes, with means for controlling the value of the current flowing through the device, whereby pixel light emission state gradation and constant current control become possible. More specifically, the invention contemplates a driving method for a switching device that includes at least two electrodes and an organic bistable material that is disposed between the electrodes and, graduated electrical resistance, with switching a steady bias voltage Vb to the bistable electrical device, to which are added voltage pulses according to at least one of the following methods: In the first, a pulse of constant width (for example, a fixed 30 μs in duration) is applied in addition to the bias voltage. This results, after the end of the pulse, in a conductance of the bistable material for the duration of the period in which the bias voltage is applied, which depends upon the voltage level of the pulse. Therefore, by varying the voltage level of the pulse, the conductance and therefore the current, during the time after the pulse ends but while the bias voltage is still being applied, are varied. This of course leads to a gradation of the light emitted by an individual LED during a frame.

In the second method, a pulse is applied that has a fixed voltage (for example, 2 volts above the bias voltage) but is of variable width (for example, between 20 and 50 μs). This results in a variable device conductance (after the end of the pulse, while the bias voltage is still being applied) that is a function of the pulse width.

### BRIEF DESCRIPTION OF THE DRAWING FIGURES

FIG. 1 is a schematic view of a bistable switching device according to an aspect of the invention.

FIG. 2 is a schematic view of a bistable switching device according to another aspect of the invention.

FIG. 3 is a schematic view of a bistable switching device showing charge accumulated at the interface between an organic bistable material and a metal electrode.

FIG. 4 is a graphical view showing the dependence of the switching device current on the voltage of a voltage pulse for Examples 1, 2, and 3.

FIG. 5 is a graphical view showing the dependence of the switching device current on the pulse width of the voltage pulse for Examples 1, 2, and 3.

FIG. 6 is a graphical view showing conceptually the general voltage-current characteristic of a bistable switching device.

FIG. 7 is a schematic view of a bistable switching device coupled with an organic light emitting diode.

FIG. 8 is a schematic view of a bistable switching device coupled with an organic light emitting diode (OLED) formed on a glass substrate.

FIG. 9 is a graphical view showing conceptually the general voltage-current characteristic of a bistable switching device with a coupled OLED.

FIG. 10 is a first graphical view showing pulses applied in a matrix of elements.

FIG. 11 is a second graphical view showing pulses applied in a matrix of elements.

### DETAILED DESCRIPTION OF THE INVENTION

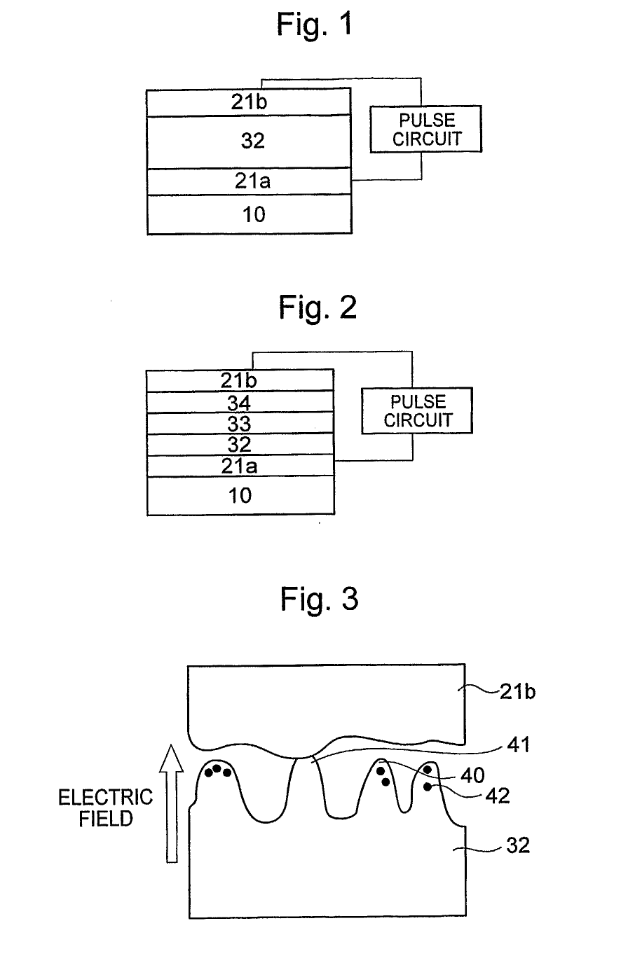

FIGS. 1 and 2 illustrate preferred constitutions of the switching device of the invention. As shown in FIG. 1, in this switching device, an electrode layer 21a, an organic bistable material layer 32, and an electrode layer 21b are formed in this order on a substrate 10. Alternatively, as shown in FIG. 2, the structure may be such that a fine metal particle dispersion layer 33 is formed within the organic bistable material layer 32 in the constitution of FIG. 1. In FIG. 2, the organic bistable material layer is thus shown divided into two parts, labeled “32” and “34.”

There are no particular limitations on the substrate 10. It is preferable to use a conventional publicly-known glass substrate or the like.

There are no particular limitations on the electrode layers 21a and 21b. It is possible in general to select a metallic material such as aluminum, gold, silver, nickel, iron or copper, an inorganic material such as ITO or carbon, an organic material such as a conjugated organic material or a liquid crystal, a semiconductor material such as silicon, or the like as appropriate.

In the invention there are many examples of the organic bistable material that may be used in the organic bistable material layer 32. These include aminoimidazole compounds, dicyano compounds, pyridone compounds, styryl compounds, stilbene compounds, butadiene compounds, and so on.

Moreover, it is preferable for these organic bistable materials to contain an electron-donating functional group and an electron-accepting functional group in a single molecule. Examples of electron-donating functional groups are —SCH₃, —OCH₃, —NH₂, —NHCH₃, —N(CH₃)₂ and so on, and examples of electron-accepting functional groups are —CN, —NO₂, —CHO, —COCH₃, —COOC₂H₅, —COOH, —Br, —Cl, —I, —OH, —F, —O, and so on.

The fine metal particle dispersion layer 33 is formed by dispersing fine metal particles in the same organic material as that used for the organic bistable material layer 32 or a different organic material. There are no particular limitations on the fine metal particles, with is being possible to select aluminum, gold, silver, nickel, iron, copper or the like as appropriate.

The electrode layer 21a, the organic bistable material layer 32, and the electrode layer 21b are preferably formed in this order as thin films on the substrate 10. As the method of forming these thin films, a vacuum process such as a vacuum deposition method or a sputtering method can be used. Alternatively an organic thin film formation method such as a spin coating method, a dipping method, a bar coating method, an ink jet method, a monomolecular film accumulation method (LB method), or a screen printing method can be used.

As the method of forming the fine metal particle dispersion layer 33, multiple vacuum deposition of an organic material and a metallic material can be used. Alternatively, an organic thin film formation method such as a spin coating method, a bar coating method, an ink jet method, a monomolecular film accumulation method (LB method) or a screen printing method can be used with a coating liquid having fine metal particles dispersed therein.

The substrate temperature during the vapor deposition in the case of using vapor deposition to form the electrode layers 21a and 21b, the organic bistable material layer 32, and the fine metal particle dispersion layer 33 can be selected as appropriate in accordance with the electrode material used, with 0° to 150° C. being preferable.

The thickness of each of the electrode layers 21a and 21b is preferably 50 to 200 nm, the thickness of the organic bistable material layer 32 is preferably 20 to 150 nm, and the thickness of the fine metal particle dispersion layer 33 is preferably 5 to 100 nm.

The reason that the resistance value in the ON state can be controlled through the driving method of the invention described above is still not clear, but a hypothetical explanation is presented below.

It is presumed that the mechanism of transfer from the high resistance state to the low resistance state is broadly speaking as follows. As shown in FIG. 3, in the high resistance state, charge is injected into the organic bistable material layer 32 from the electrode layer 21a via a tunnel current or the like. The injected charge is captured and accumulates on the fine metal particles 40 of the fine metal particle dispersion layer 33 or at the interface of the organic bistable material layer 32 with the electrode layer 21b. As a result of this accumulation of charge, the electric field in the organic bistable material layer 32 increases, and it is presumed that once this reaches a certain electric field, the charge is injected suddenly into the organic bistable material layer 32 from the electrode layer or the fine metal particles (i.e., the device transfers to ON state).

The current value in the ON state depends on the amount of increase in the electric field and the amount of charge injected, and these things are determined by the amount of charge accumulated on the fine metal particles or at the organic/metal interface. The switch-over from the high resistance state to the low resistance state in the switching device is carried out by applying a voltage pulse no less than a threshold value; the above-mentioned accumulated charge depends on the tunnel current, which depends on the switching voltage pulse, and hence the current value in the ON state can be controlled via the amount of accumulated charge through the value of the switching voltage or the pulse width.

The invention contemplates controlling the amount of the accumulated charge, which in turn controls the current through the device when a bias voltage is applied.

### EXAMPLES

Several specific examples are described below.

### Example 1

A switching device having a constitution as shown in FIG. 2 was manufactured through the following procedure.

Using a glass substrate as a substrate 10, films were formed including aluminum as an electrode layer 21a, an organic, bistable material layer 32, a fine metal particle dispersion layer 33, an organic bistable material layer 34, and aluminum as an electrode layer 21b. These were formed as thin films, in this order, using a vacuum deposition method, thus forming the switching device of Example 1. A carbonitrile compound of structural formula (I), shown below, was used for the organic bistable material layers 32 and 34, and the fine metal particle dispersion layer 33 was formed by dispersing fine aluminum particles in the carbonitrile compound of below-mentioned structural formula (I).

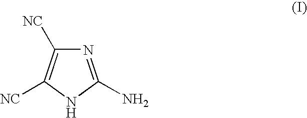

The electrode layer 21a and the electrode layer 21b were formed orthogonal to one another, each to a width of 0.5 mm, and the organic bistable material layer 32, the fine metal particle dispersion layer 33, and the organic bistable material layer 34 were formed over the whole of the substrate.

Electrical measurements were carried out at the part of area, measuring 0.5 mm×0.5 mm, where the electrode layer 21a and the electrode layer 21b intersected one another. Moreover, the electrode layer 21a, the organic bistable material layer 32, the fine metal particle dispersion layer 33, the organic bistable material layer 34, and the electrode layer 21b were deposited to thicknesses of 100 nm, 40 nm, 30 nm, 40 nm, and 100 nm respectively. The deposition was carried out under a vacuum of 3×10⁻⁶ torr, with exhaustion being carried out using a diffusion pump. The deposition of the carbonitrile compound was carried out at a deposition rate of 0.2 □/s using a resistive heating method, and the deposition of the aluminum was carried out at a deposition rate of 1.5 A/s using a resistive heating method.

### Example 2

The switching device of Example 2 was obtained under the same conditions as in Example 1, except that an aluminum quinoline compound of structural formula (II) was used as the organic bistable material in the layer 32, 33, 34.

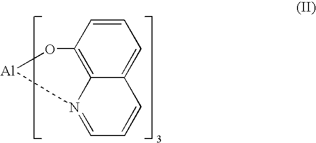

### Example 3

The switching device of Example 3 was obtained under the same conditions as in Example 1, except for the following: A quinomethane compound of structural formula (III) was formed to a thickness of 80 nm as the organic bistable material layer 32, the fine metal particle dispersion layer 33 and the organic bistable material layer 34 were not formed, and gold was used as the material of the electrode layer 21b. This example is illustrated in FIG. 1.

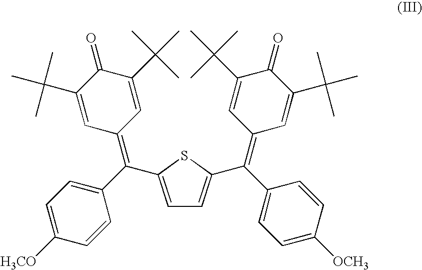

The chemical materials of Examples I and II were purchased from the Aldrich chemical company, and the material of Example III can be synthesized by a person skilled in the art.

Testing

For each of the switching devices of Examples 1 to 3 described above, the current-voltage characteristic was measured at room temperature using the following procedure. First, the voltage was raised at a rate of 0.1 V/s from zero to the voltage Vth2 at which transfer from the OFF state to the ON state was observed, whereby the static Vth2 was measured. The results are shown in Table 1. Next, for each of the devices, a voltage of 80% of the respective Vth2 was applied as a bias voltage Vb, and a voltage pulse was superimposed (or added) on this, thus bringing about transfer from the high resistance state to the low resistance state. Taking the superimposed voltage of the voltage pulse and the temporal pulse width of the voltage pulse as parameters, the current value at a voltage of Vb in the low resistance state was measured.

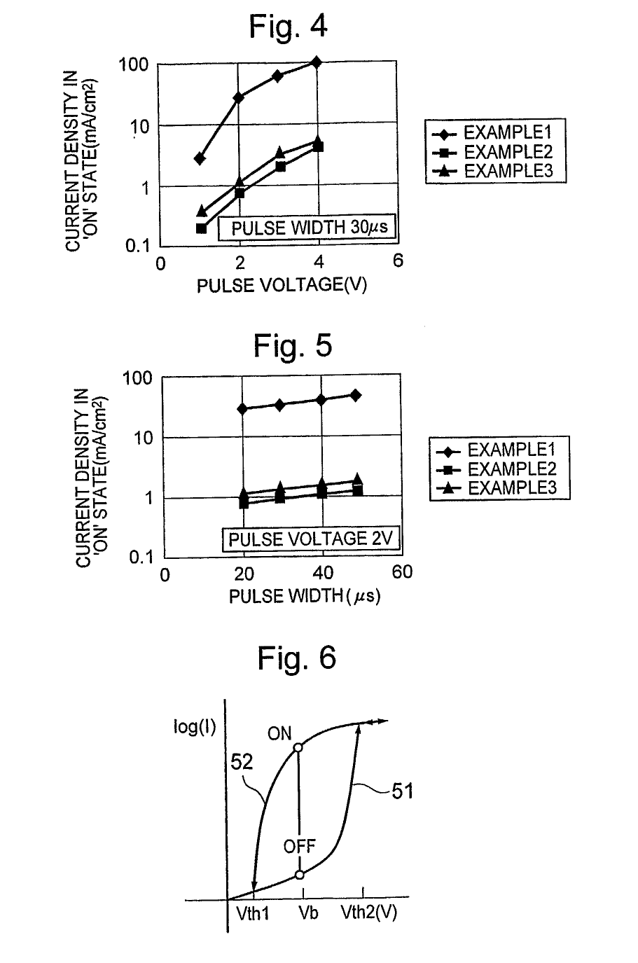

The results are shown in FIGS. 4 and 5. In FIG. 4, the pulse width was held at 30 μs and the voltage pulse was changed. In FIG. 5, the superimposed (added) voltage pulse was held at 2 V and the pulse width was changed. It is clear that for all of the Examples I-III, the current value in the ON state rises in accordance with, and can thus be controlled through, the voltage value or the pulse width of the switching pulse.

TABLE 1

| Example | Vth2 |
|---|---|
| 1 | 2.4 V |
| 2 | 1.8 V |
| 3 | 4.8 V |

As noted, the usable range of the value of Vb is between Vth1 and Vth2 in the viewpoint of “switching”. However, in practical use, a high value of Vb is preferred to obtain high current. At a value of Vb too close to Vth2, however, the behavior might be unstable because of the variance of Vth2 value. Therefore, from this standpoint, a preferred range of Vb would appear to be from (0.5*Vth1+0.5*Vth2) to (0.1*Vth1+0.9Vth2).

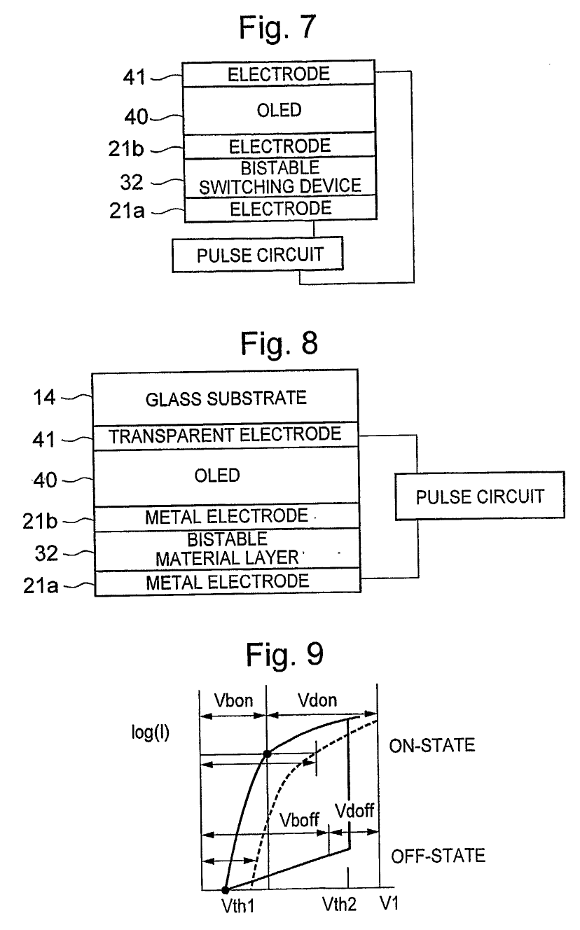

FIG. 7 shows a bistable electrical device similar to that of FIG. 1, but coupled to (in series with) an organic light emitting diode (OLED) 40 with an additional electrode 41. FIG. 8 shows this structure mounted on a glass substrate 14. FIG. 9 is similar to FIG. 6 but shows the voltage across the OLED in dotted line and the voltage across the bistable electrical device in full line. The voltage is divided between the two devices in proportion to their impedance. In this case, the write pulse height for a write process is preferably no more than (Vth2-Vboff), and the write pulse height for an erase process is preferably no more than (Vbon-Vth1).

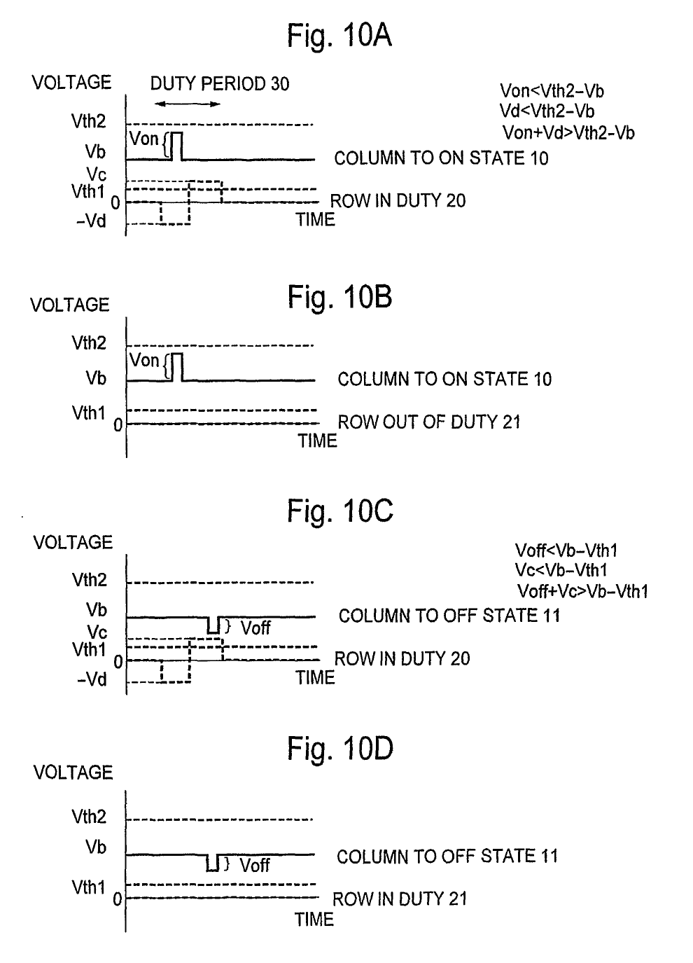

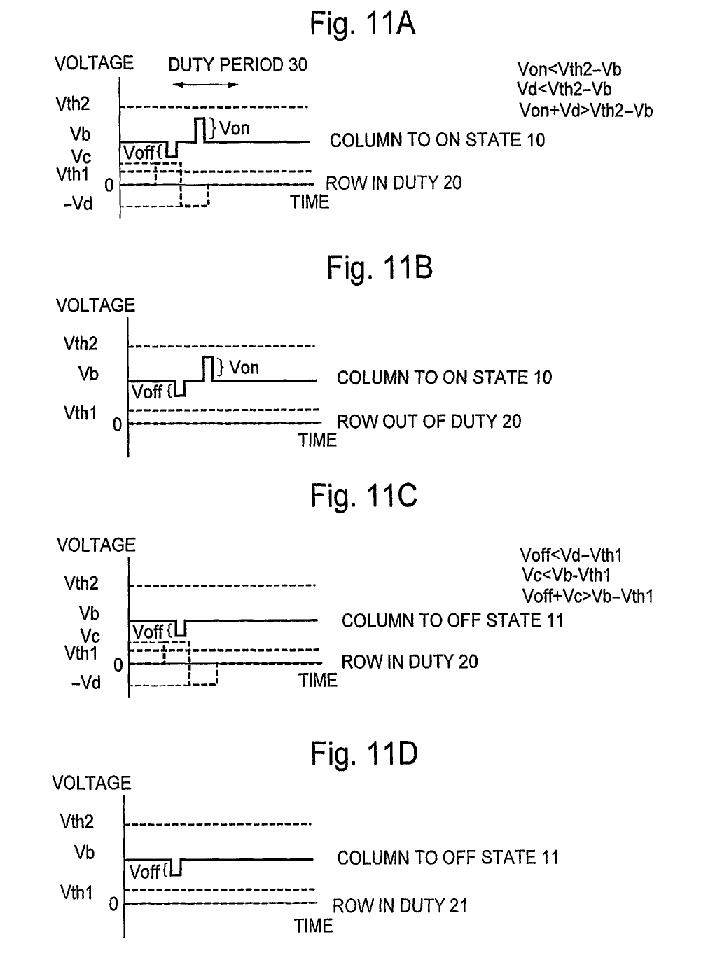

FIG. 10 illustrates how a bistable electrical device in a display matrix (one device for each pixel) could be switched by a combination of switching pulses of rows and columns, when the device has the I-V characteristics shown in FIG. 6. Turn-on (write) pulses should be more than (Vth2-Vb), and turn-off (erase) pulses should be no more than (Vb-Vth1). In duty period 30, the voltage of the row line in duty is controlled as shown by curve 20, whereas the voltage of the row line out of duty is shown by curve 21. For columns to be written, the voltage is shown by curve 10 in part (a) of FIG. 10, while columns to be erased, the voltage is shown by curve 11 in part (c) of FIG. 10. The bias applied to each pixel is the voltage difference between the column line and the row lines. Thus, the write pulse height is obtained by a combination of Von at the column line and Vd at the row line, and erase pulse height is obtained by a combination of Voff at the column line and Vc at the row line. By choosing the values of Von, Vd, Voff, and Vc as shown, switching is not triggered at other pixels where the voltage changes of both lines are not applied (parts (b) and (d) of FIG. 10).

In the case of Example 3, the quinomethane materials, the morphology of the gold of the electrode may be important because its appears to play an important role for the bistable behavior. In FIG. 3, the charge accumulation at the metal/organic interface appears to be the origin of the bistability, especially in case of the quinomethane materials.

Further testing results are disclosed in a paper entitled “Organic Bistable Devices with High Switching Voltage,” presented by Haruo Kawakami et al., Fuji Electric Advanced Technology Corporate Ltd., Hino-city, Japan at “The International Symposium on Optical Science and Technology SPIE's 49^{th} Annual Meeting,” Denver, Colo., August 2004, in which bistable behavior of the quinomethane material of Example 3 is further described. Further results were presented by the applicant at the proceeding of “The International Symposium on Super-Functionality Organic Devices” Chiba, Japan, October 2004. The latter shows the behavior of several kinds of quinomethane compounds, with various A or R groups, and show that compounds with a dipole moment more than 6 Debye have bistable behavior. Thus, a high molecular dipole moment promotes the bistable behavior. Both of these disclosures are incorporated herein by reference.

### EFFECTS OF THE INVENTION

As described above, according to the invention, in the case of a switching device in which an organic bistable material is disposed between two electrodes, means can be provided that enables the value of the current flowing through the device to be controlled, whereby pixel light emission state gradation and constant current control become possible. This switching device can thus be favorably used as a switching device for driving an organic light emitting diode display panel.

Incorporated herein in its entirely by reference, along with references cited therein, is Bozano et al., Mechanism for bistability in organic memory elements, Appl. Phys. Lett. vol. 84 no. 4, p. 607 (Jan. 26, 2004).

All references that are cited in any and all of the references explicitly incorporated herein by reference also are incorporated herein by reference.

We claim:

1. In combination:
(a) a bistable electrical device which is convertible between a low resistance state and a high resistance state, comprising
a first electrode,
a second electrode, and
an organic material between the electrodes such that the bistable electrical device is convertible to a high resistance state by application of a turn-off voltage to the first and second electrodes, and is convertible to a low resistance state by application of a turn-on voltage to the first and second electrodes; and
(b) circuitry applying to the first and second electrodes
a substantially constant bias voltage that is intermediate the turn-off voltage and the turn-on voltage of the bistable electrical device, and
electrical pulses variable in a temporal pulse width or variable in an additional voltage, or variable in both, wherein the additional voltage is superimposed on the bias voltage while the pulse is applied to the bistable electrical device;
whereby a current flowing through the bistable electrical device due to the bias voltage is controlled by varying the pulse width or the additional voltage.

2. The combination of claim 1, wherein the circuitry applies to the bistable electrical device pulses of varying temporal pulse width and a constant additional voltage, whereby the current flowing through the bistable electrical device, after the pulse, is controlled by changing the pulse width.

3. The combination of claim 2, wherein the constant additional voltage is approximately 2 V.

4. The combination of claim 2, wherein the pulse width varies between approximately 20 μs and approximately 50 μs.

5. The combination of claim 1, wherein the circuitry applies to the bistable electrical device pulses of constant temporal pulse width and a varying additional voltage, whereby the current flowing through the bistable electrical device, after the pulse, is controlled by changing the variable additional voltage.

6. The combination of claim 5, wherein the additional voltage varies between approximately 1 V and approximately 4 V.

7. The combination of claim 5, wherein the constant temporal pulse width is approximately 30 μs.

8. The combination of claim 1, wherein a sum of the bias voltage and the additional voltage is not less than the turn-on value.

9. The combination of claim 1, wherein the organic material comprises a carbonitrile compound of structural formula 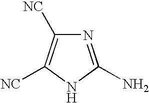
and wherein the bias voltage is approximately 2.4 V.

10. The combination of claim 1, wherein the organic material comprises an aluminum quinoline compound of structural formula 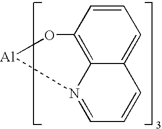
and wherein the bias voltage is approximately 1.8 V.

11. The combination of claim 1, wherein the organic material is a quinomethane compound.

12. The combination of claim 1, wherein the organic material comprises a quinomethane compound of structural formula

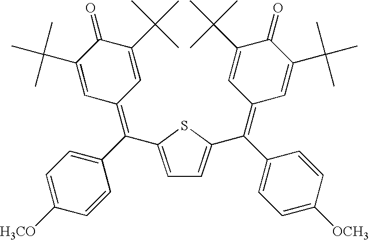

13. The combination of claim 12, wherein the bias voltage is approximately 4.8 V.

14. The combination of claim 12, wherein the second electrode of formed of gold.

15. The combination of claim 1, wherein the bistable material includes only low conductivity material and the second electrode of formed of gold.

16. The combination of claim 15, wherein the low conductivity material comprises a quinomethane compound with a dipole moment more than 6 Debye.

17. The combination of claim 1, wherein the organic material includes low conductivity organic material and, mixed with the low conductivity material, a sufficient amount of a high conductivity material that the bistable electrical device is convertible to the high resistance state by application of the turn-off voltage to the first and second electrodes, and is convertible to the low resistance state by application of the turn-on voltage to the first and second electrodes.

18. The combination of claim 17, wherein the high conductivity material includes fine metallic particles in a dispersion layer, the dispersion layer sandwiched between two layers of the low conductivity organic material.

19. The combination of claim 1, comprising an organic light emitting diode, whereby the combination constitutes an electroluminescent device, and wherein a brightness of light emitted by the light emitting diode, after the pulse, is graduated according to the current flowing through the bistable electrical device.

20. A method of driving a bistable electrical device which is convertible between a low resistance state and a high resistance state, the device further comprising
a first electrode,
a second electrode,
an organic material between the electrodes such that the bistable electrical device is convertible to a high resistance state by application of a turn-off voltage to the first and second electrodes, and is convertible to a low resistance state by application of a turn-on voltage to the first and second electrodes;
the method comprising:
applying to the first and second electrodes
a substantially constant bias voltage that is intermediate the turn-off voltage and the turn-on voltage of the bistable electrical device, and
electrical pulses variable in a temporal pulse width or variable in an additional voltage, or variable in both, wherein the additional voltage is superimposed on the bias voltage while the pulse is applied to the bistable electrical device;
whereby a current flowing through the bistable electrical device due to the bias voltage is controlled by varying the pulse width or the additional voltage.

21. The method of claim 20, comprising applying to the bistable electrical device pulses of varying temporal pulse width and a constant additional voltage, whereby the current flowing through the bistable electrical device, after the pulse, is controlled by changing the pulse width.

22. The method of claim 21, wherein the constant additional voltage is approximately 2 V.

23. The method of claim 21, wherein the pulse width varies between approximately 20 μs and approximately 50 μs.

24. The method of claim 20, comprising applying to the bistable electrical device pulses of constant temporal pulse width and a varying additional voltage, whereby the current flowing through the bistable electrical device, after the pulse, is controlled by changing the variable additional voltage.

25. The method of claim 24, wherein the additional voltage varies between approximately 1 V and approximately 4 V.

26. The method of claim 24, wherein the constant temporal pulse width is approximately 30 μs.

27. The method of claim 20, wherein the bias voltage is approximately 80% of the turn-on voltage.

28. The method of claim 20, wherein a sum of the bias voltage and the additional voltage is not less than the turn-on value.

29. The method of claim 20, comprising providing an organic light emitting diode, whereby a combination of the bistable electrical device and the organic light emitting diode constitutes an electroluminescent device, and wherein a brightness of light emitted by the light emitting diode, after the pulse is graduated according to the current flowing through the bistable electrical device.

30. The method of claim 20, wherein the organic material includes low conductivity organic material and, mixed with the low conductivity material, a sufficient amount of a high conductivity material that the bistable electrical device is convertible to the high resistance state by application of the turn-off voltage to the first and second electrodes, and is convertible to the low resistance state by application of the turn-on voltage to the first and second electrodes.

31. The combination of claim 20, wherein the high conductivity material includes fine metallic particles in a dispersion layer, the dispersion layer sandwiched between two layers of the low conductivity organic material.

32. The method of claim 20, wherein the organic material is a quinomethane compound.

33. The method of claim 20, wherein the organic material comprises a quinomethane compound of structural formula

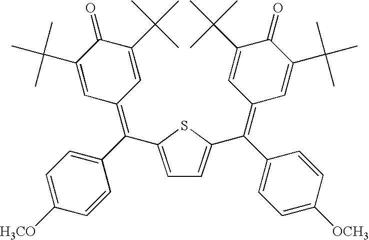

34. The method of claim 33, wherein the bias voltage is approximately 4.8 V.

35. The method of claim 33, wherein the second electrode of formed of gold.

36. The method of claim 18, wherein the bias voltage Vb is in the range (0.5*Vth1+0.5*Vth2) to (0.1*Vth1+0.9Vth2), wherein Vth1 is the turn-off voltage and wherein Vth2 is the turn-on voltage.
